(19) United States
(12) Patent Application Publication
(10) Pub. No.: US 2016/0300998 A1
(43) Pub. Date: Oct. 13, 2016

(54) METHOD FOR PRODUCING MAGNETOSTRICTIVE MATERIAL

(71) Applicants: HIROSAKI UNIVERSITY, Hirosaki-shi, Aomori (JP); TOHOKU UNIVERSITY, Sendai-shi, Miyagi (JP); TOHOKU STEEL Co., Ltd., Shibata-gun, Miyagi (JP)

(72) Inventors: Yasufumi FURUYA, Hirosaki-shi (JP); Shinichi YAMAURA, Sendai-shi (JP); Takashi NAKAJIMA, Sendai-shi (JP); Takashi EBATA, Shibata-gun (JP); Takenobu SATO, Shibata-gun (JP)

(73) Assignees: HIROSAKI UNIVERSITY, Hirosaki-shi, Aomori (JP); TOHOKU UNIVERSITY, Sendai-shi, Miyagi (JP); TOHOKU STEEL Co., Ltd., Shibata-gun, Miyagi (JP)

(21) Appl. No.: 15/102,244

(22) PCT Filed: Dec. 5, 2014
(86) PCT No.: PCT/JP2014/082249

§ 371 Date: Jun. 6, 2016

(30) Foreign Application Priority Data
Dec. 6, 2013 (JP) 2013-253586

(51) Int. Cl. H01L 41/47; H01L 41/20; H01L 41/12; C22F 1/10; C22C 19/07

(52) U.S. Cl. CPC H01L 41/47; C22F 1/10; C22C 19/07; H01L 41/125; H01L 41/20

(57) ABSTRACT

A method for producing a magnetostrictive material and a method for increasing the value of magnetostriction can increase the value of magnetostriction of magnetostrictive materials used, for example, in vibration power generation and force sensors utilizing inverse magnetostriction phenomenon. A magnetostrictive material having a value of magnetostriction of 100 ppm or more is produced by melting and casting an alloy material in the composition of range of 67-87 wt % Co with the balance consisting of Fe and unavoidable impurities and then performing hot forging. Furthermore, a magnetostrictive material having a value of magnetostriction of 130 ppm or more can be produced by performing cold rolling after the hot forging. Heat treatment at 400-1000° C. may also be performed after hot working or cold working.

### FIELD OF THE INVENTION

The present invention relates to a method for producing a magnetostrictive material and a method for increasing the amount of magnetostriction.

### RELATED ART

Magnetostrictive materials have been used in vibration power generation and force sensors utilizing an inverse magnetostriction phenomenon in which a magnetic field within a magnetic material undergoes a change due to a strain produced by external stress loading.

Fe—Co alloys (Co: 56 to 80% by atom) having material ductility and workability improved over those of Tb—Dy—Fe alloys (Terfenol-D) and FeGa alloys (Galfenol) that are magnetostrictive alloys for vibration power generation and have hitherto been tested, and a method for heat treatment thereof are provided by Furuya et al. (see Patent Document 1).

### CITATION LIST

### Patent Literature

### [Patent Document 1] Japanese Unexamined Patent Application, Publication No. 2013-177664

### SUMMARY

### Technical Problem

However, it is difficult to stably bring the amount of magnetostriction to 100 ppm or more by the method described in Patent Document 1, and a method for mass production of alloy materials that can provide an amount of magnetostriction of not less than 100 ppm that are practical in the utilization of an inverse magnetostriction effect has been desired. In the method described in Patent Document 1, since casting (such as centrifugal casting) is performed into dimensions and shapes close to those in use, an advantage of small working manhours such as machining necessary after that can be offered. Since, however, this method mainly relies upon heat treatment and composition substantially without plastic working, the amount of magnetostriction that strongly depends upon crystalline structure, strain and defects cannot be satisfactorily regulated, posing a problem that the amount of magnetostriction that can be stably provided is approximately on the order of 90 ppm at the highest.

The present inventors have drawn attention to this problem, and an object of the present invention is to provide a method for producing a magnetostrictive material and a method for increasing an amount of magnetostriction that can increase the amount of magnetostriction in magnetostrictive materials used, for example, vibration power generation and force sensors utilizing an inverse magnetostriction phenomenon.

### Solution to Problem

The present inventors have found that an amount of magnetostriction of not less than 100 ppm can be stably provided when a bulk magnetostrictive material is produced by melting and casting a material comprising 67 to 87% by mass of Co with the balance consisting of Fe and unavoidable impurities and then performing hot working and optionally cold working.

The above object can be attained by a method for producing a magnetostrictive material, the method comprising subjecting an alloy material for a magnetostrictive material to hot working.

A magnetostrictive material having a large amount of magnetostriction can be produced by subjecting an alloy material for a magnetostrictive material to hot working.

According to another aspect of the present invention, there is provided a method for increasing an amount of magnetostriction of a magnetostrictive material, the method comprising subjecting a magnetostrictive material to hot working and optionally cold working and/or heat treatment.

In the present invention, the amount of magnetostriction can be increased by subjecting a magnetostrictive material to hot working and optionally cold working and/or heat treatment. In the present invention, the cold working and the heat treatment are not indispensable steps, and any of only hot working, a combination of hot working with cold working, a combination of hot working with heat treatment, and a combination of hot working with cold working and heat treatment may be adopted.

In the present invention, hot working may be any working that can realize hot plastic deformation. Hot forging or hot rolling is particularly preferred, and hot blooming may also be possible. The hot forging may be performed using, for example, pressing machines or hammers. The hot rolling may be performed using, for example, roll mills. Cold rolling is preferably performed after hot rolling. The amount of magnetostriction can be further increased by performing cold working after hot working. In the present invention, the cold working may be any working that can realize cold plastic deformation. Cold rolling is preferred, and cold wire drawing is also possible. A temperature from room temperature to about 300° C. is regarded as being cold in an environment of a production workplace.

In the present invention, preferably, the alloy material is an Fe—Co-base magnetostrictive material, and the magnetostrictive material is an Fe—Co-base bulk magnetostrictive material. Particularly preferably, the alloy material has been produced by melting and solidifying a material comprising 67 to 87% by mass of Co with the balance consisting of Fe and unavoidable impurities. In this case, a magnetostrictive material having an amount of magnetostriction of not less than 100 ppm can easily be produced. Further, preferably, the alloy material has been produced by melting and solidifying a material comprising 71 to 82% by mass of Co with the balance consisting of Fe and unavoidable impurities. The amount of magnetostriction of the magnetostrictive material can be enhanced to not less than 130 ppm by subjecting the alloy material having this composition to cold working after hot working.

In the present invention, the alloy material has been produced by melting and solidifying a material comprising 67 to 87% by mass of Co and not more than 1% by mass of one of or a combination of two or more of Nb, Mo, V, Ti, and Cr with the balance consisting of Fe and unavoidable impurities. In this case, the amount of magnetostriction of the produced magnetostrictive material is somewhat smaller than that when Nb, Mo, V, Ti, or Cr is not added, but on the other hand, mechanical strength, particularly tensile strength, can be increased. When a combination of two or more of Nb, Mo, V, Ti, and Cr is contained, the total amount (% by mass) of the combined elements is not more than 1% by mass.

In particular, when the alloy material has been produced by melting and solidifying a material comprising 67 to 72% by mass of Co and not more than 0.6% by mass of one of or a combination of two or more of Nb, Mo, V, Ti, and Cr with the balance consisting of Fe and unavoidable impurities, cold working after hot working can realize an enhancement in the amount of magnetostriction of the magnetostrictive material to not less than 110 ppm and an enhancement in mechanical strength.

The magnetostrictive material having an enhanced mechanical strength is suitable for applications such as devices that are required to be durable, for example, vibration power generation and sensors utilizing an inverse magnetostriction effect.

In the present invention, the hot working is preferably performed at a temperature of 1200° C. or below, more preferably performed by heating the material at 900 to 1100° C., then taking the material out of a furnace, and plastically deforming the material at a temperature between 1100° C. and 700° C. The alloy material is preferably a melting bulk material having a size large enough to perform working such as hot forging or hot blooming using, for example, a pressing machine or a hammer and hot rolling or cold rolling using a roll mill.

After hot working or cold working, the material may be heat-treated at a temperature that is not above a (bcc+fcc)/bcc phase boundary in an Fe—Co-base binary phase diagram. In a specific temperature range, the material may be heat-treated at 400 to 1000° C. after hot working or cold working.

The shape of the magnetostrictive material after hot working or cold working is not limited, and examples thereof include rod, wire, and plate shapes.

### Effect of the Invention

The present invention can provide a method for producing a magnetostrictive material and a method for increasing an amount of magnetostriction that can enhance the amount of magnetostriction of magnetostrictive materials used, for example, in vibration power generation and force sensors utilizing an inverse magnetostriction phenomenon.

### BRIEF DESCRIPTION OF THE DRAWINGS

FIG. 1 is a graph illustrating, for each production method, a relationship between the composition of an alloy material in Example 1 of the present invention and the amount of magnetostriction.

FIG. 2 is an Fe—Co-base binary phase diagram.

FIG. 3 is a graph illustrating, for each Co content (% by mass), a relationship between the amount of addition elements in Example 2 of the present invention and the tensile strength.

FIG. 4 is a graph illustrating, for each Co content (% by mass), a relationship between the amount of addition elements in Example 2 of the present invention and the amount of magnetostriction.

### MODE FOR CARRYING OUT THE INVENTION

Embodiments of the present invention will be described with reference to the accompanying drawings.

Ingredients: Co: 67 to 87% by mass and balance: Fe and unavoidable impurities.

Bulk magnetostrictive materials having an amount of magnetostriction of not less than 100 ppm can be produced by melting and casting an alloy material having this composition and then hot-forging the casting product. Further, the amount of magnetostriction can be further increased by performing cold rolling after hot forging. Hot rolling may be performed after hot forging. Alternatively, cold rolling may be performed after hot rolling.

Ingredients: Co: 71 to 82% by mass and balance: Fe and unavoidable impurities.

Bulk magnetostrictive materials having an amount of magnetostriction of not less than 110 ppm can be produced by melting and casting an alloy material having this composition and then hot-forging the casting product. Further, magnetostrictive materials having an amount of magnetostriction of not less than 130 ppm can be produced by performing cold rolling after hot forging.

Ingredients: Co: 76 to 82% by mass and balance: Fe and unavoidable impurities.

Magnetostrictive materials having an amount of magnetostriction of not less than 150 ppm can be produced by melting and casting an alloy material having this composition, then hot-forging the casting product, and further cold-rolling the forged product.

Ingredients: Co: 67 to 87% by mass, one of or a combination of at least two of Nb, Mo, V, Ti, and Cr, and balance: Fe and unavoidable impurities.

Magnetostrictive materials having an amount of magnetostriction of 65 to 139 ppm and a tensile strength of 695 to 1010 MPa can be produced by melting and casting an alloy material having this composition, then subjecting the casting product to hot forging, and further subjecting the forging product to cold drawing.

Hot Working and Cold Working

The amount of magnetostriction is increased by working such as hot or cold forging, rolling, and wire drawing. It is considered that the amount of magnetostriction undergoes a complicated influence of crystalline structures, strains, lattice defects and the like.

Heat Treatment at 400 to 1000° C.

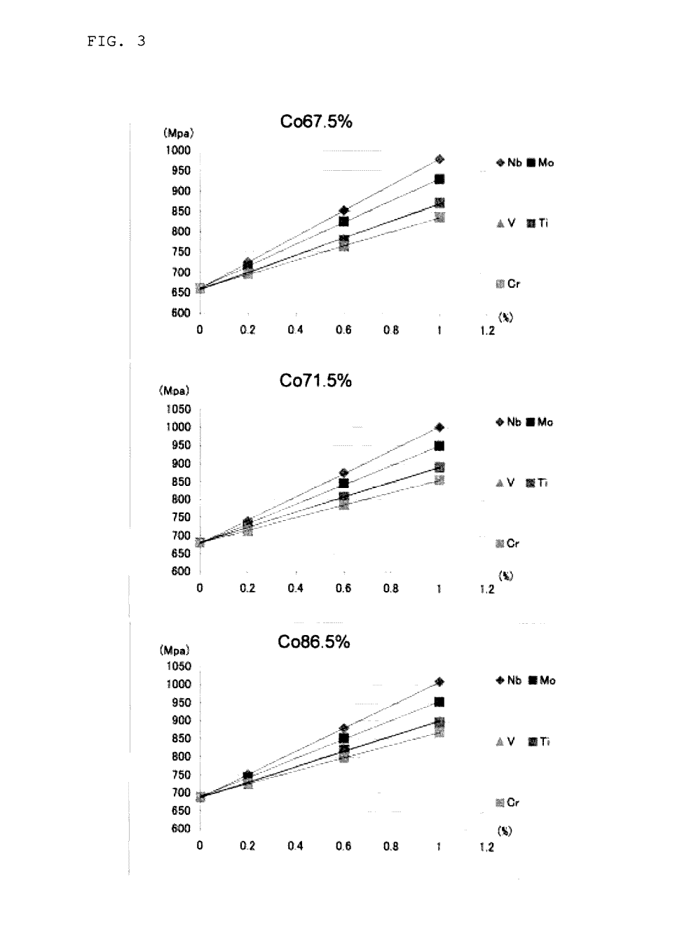

The amount of magnetostriction is not significantly lowered even when, after hot working and cold working, the material is heat-treated at 400 to 1000° C. with a view to relieving strains. Further, heat treatment may be performed between hot working and cold working. Heat treatment at 1000° C. or above sometimes causes a significant lowering in the amount of the magnetostriction. For example, the precipitation of the fcc phase is considered to be causative of this lowering. An Fe—Co-base binary phase diagram is illustrated in FIG. 2.

Next, one example of the method for producing an Fe—Co-base bulk magnetostrictive material in an embodiment of the present invention will be described.

For example, in an induction furnace under an atmosphere, an alloy material having the above composition is melted and refined and is then subjected to ingot casting. The ingot is then heated to 900 to 1100° C., is taken out from the furnace, and is then subjected to hot working (for example, hot forging, hot rolling, or hot rolling after hot forging) into rod, wire, or plate shapes. Next, for wire rod production, the material is subjected to cold drawing and as such is further brought into thin wire rods, or is brought into bend-straightened rods. For rod production, cold bend straightening is performed. For plate production, the bend-straightened material as such may be used as a plate or alternatively may be cold-rolled into a thinner plate or a strip. The wire rod, rod, plate, or strip thus produced is used either as such or after working into a shape in use. Further, heat treatment at 400 to 1000° C. may be performed before use.

### EXAMPLES

### Example 1

7 kg of an alloy material comprising Co (each amount (% by mass) specified in Table 1) with the balance consisting of Fe and unavoidable impurities was melted in an Ar gas stream and was poured into a mold to prepare a cast ingot of about 80 mmφ (a melting step in tests (1) to (5) in Table 1).

Next, in tests (1) to (4) in Table 1, the ingot was held in a gas burner heating furnace of 1000 to 1100° C. for one hr, was then taken out from the furnace, and was formed into an about 15 mm-thick plate using an air hammer for hot forging (a hot forging step).

Next, in tests (1) and (2) in Table 1, the 15 mm-thick plate was formed into a 0.3 mm-thick plate by a roll-type cold rolling machine (a cold rolling step). Further, in test (2) in Table 1, the plate was held in an electric furnace at 800° C. for one hr and was then cooled in the furnace (a heat treatment step).

Further, in tests (3) and (4) in Table 1, the 15 mm-thick plate was held in an electric furnace at 1100° C. for one hr and was then rolled into a 1 mm-thick plate by a roll-type hot rolling machine (a hot rolling step). Further, in test (4) in Table 1, the plate was held in an electric furnace at 800° C. for one hr and was then cooled in the furnace (a heat treatment step).

In test (5) in Table 1, a sample was taken off from the as-cast state after melting, was held in an electric furnace at 800° C. for one hr and was then cooled in the furnace (a heat treatment step).

Thus, bulk magnetostrictive materials were produced by the tests (1) to (5).

The sample for magnetostriction measurement was formed into a size of 8 mm in length×5 mm in width×0.3 mm in thickness and was then bonded to a strain gauge (“KFL-05-120-C1-11L1M2R,” manufactured by KYOWA ELECTRONIC INSTRUMENTS CO., LTD.) with an adhesive (“M-Bond610,” manufactured by VISHAY Intertechnology, Inc.). In the magnetostriction measurement, a maximum field of 12 kOe was applied with a vibrating sample magnetometer (“VSM-5-10,” manufactured by TOEI KOGYO CO., LTD.) at room temperature, and a change in resistance of the strain gauge was measured with a multi-input data collection system (“NR-600” (attached with a strain measuring unit “NR-ST04”) manufactured by KEYENCE CORPORATION) to determine the amount of magnetostriction.

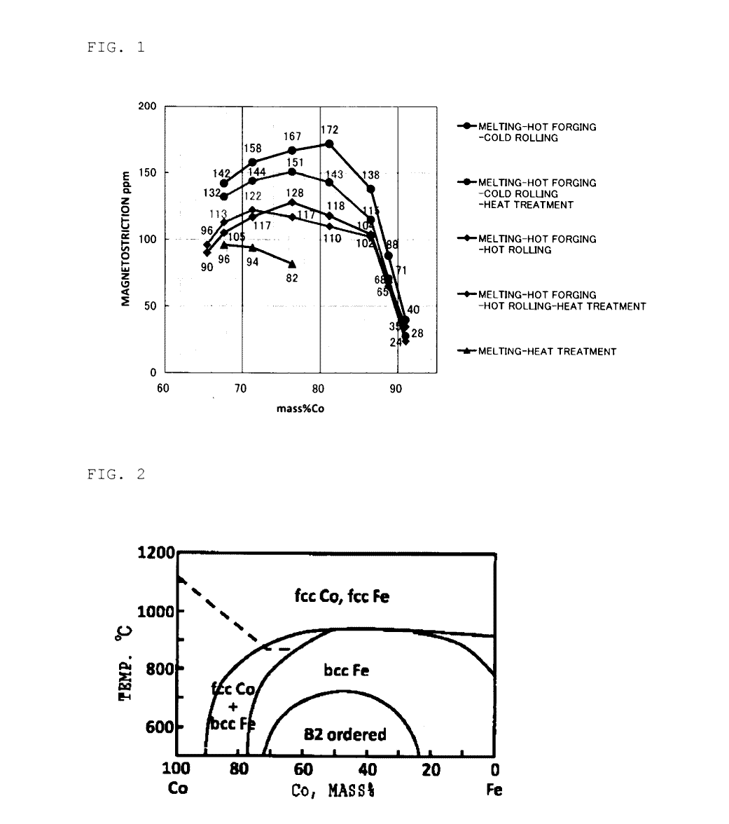

The results are shown in Table 1 and FIG. 1.

As shown in Table 1 and FIG. 1, in the tests (1) to (4), when the material had a composition comprising 67 to 87% by mass of Co with the balance consisting of Fe and unavoidable impurities, for all the samples, a large amount of magnetostriction of more than 100 ppm was obtained.

By contrast, in the tests (1) to (4), when the material had a composition outside the composition comprising 67 to 87% by mass of Co with the balance consisting of Fe and unavoidable impurities, the amount of magnetostriction was less than 100 ppm. Further, even when the composition range is the same as that in the tests (1) to (4), for the sample in the test (5) where the hot plastic working was not performed, the amount of magnetostriction was less than 100 ppm.

TABLE 1

| | Production | ingredient (Co in mass %) | | | | | | | |
|---|---|---|---|---|---|---|---|---|---|
| Test No. | step | 65.4 | 67.6 | 71.3 | 76.4 | 81.2 | 86.5 | 88.8 | 91.0 |
| 1 | Melting | | 142 | 158 | 167 | 172 | 138 | 88 | 40 |
| | Hot Forging | | | | | | | | |
| | Cold Rolling | | | | | | | | |
| 2 | Melting | | 132 | 144 | 151 | 143 | 115 | 71 | 28 |
| | Hot Forging | | | | | | | | |
| | Cold Rolling | | | | | | | | |
| | Heat Treatment | | | | | | | | |
| 3 | Melting | 90 | 105 | 117 | 128 | 118 | 104 | 68 | 35 |
| | Hot Forging | | | | | | | | |
| | Hot Rolling | | | | | | | | |
| 4 | Melting | 96 | 113 | 122 | 117 | 110 | 102 | 65 | 24 |
| | Hot Forging | | | | | | | | |
| | Hot Rolling | | | | | | | | |
| | Heat Treatment | | | | | | | | |
| 5 | Melting | | 96 | 94 | 82 | | | | |
| | Heat Treatment | | | | | | | | |

### Example 2

7 kg of an alloy material comprising Co (each amount (% by mass) specified in Tables 2 and 3) and Nb, Mo, V, Ti, or Cr (each amount (% by mass)) with the balance consisting of Fe and unavoidable impurities was melted in an Ar gas stream and was poured into a mold to prepare a cast ingot of about 80 mmφ (a melting step).

Next, the ingot was held in a gas burner heating furnace of 1.000 to 1100° C. for one hr, was then taken out from the furnace, and was formed into a size of about 16 mmφ using an air hammer for hot forging (a hot forging step).

Next, the material was then subjected to cold drawing into a wire rod of about 8 mmφ (a cold drawing step), and the wire rod was held in an electric furnace at 800° C. for one hr and was then cooled in the furnace (a heat treatment step).

Thus, magnetostrictive materials were produced.

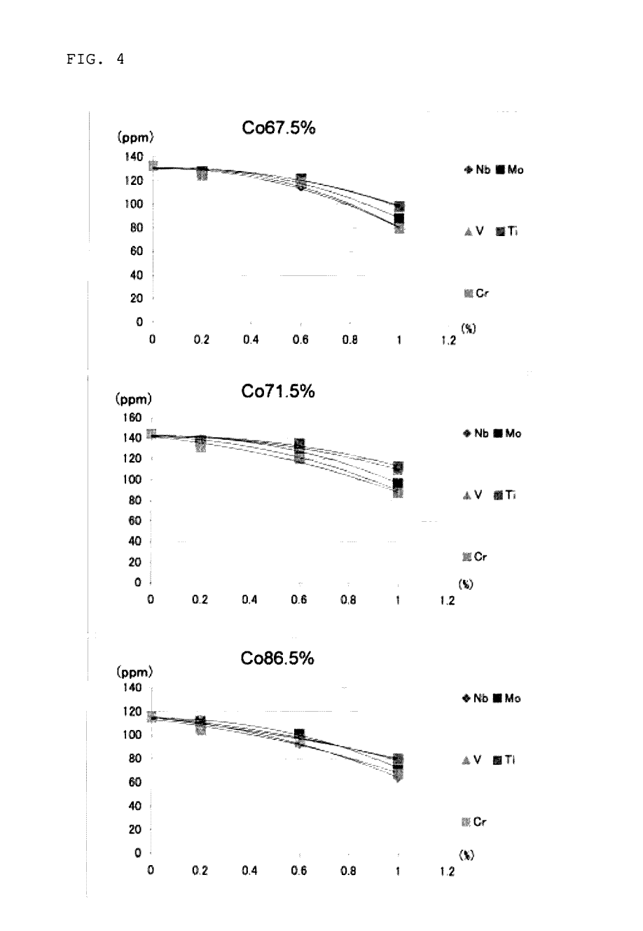

JIS14A tensile specimens of 4 mmφ and samples for magnetostriction measurement having a size of 8 mm in length×5 mm in width×0.3 mm in thickness were prepared from the produced magnetostrictive materials and were used for tests. The tensile strength was measured with an Instron tensile testing machine. The results are illustrated in Table 2 and FIG. 3. The magnetostriction measurement was performed in the same manner as in Example 1. The results are illustrated in Table 3 and FIG. 4.

As illustrated in Table 2 and FIG. 3, when the content of Co was 67.5 to 86.5% by mass, the tensile strength increased proportionally with the addition amount (not more than 1% by mass) of additive elements. Further, as illustrated in Table 3 and FIG. 4, when the content of Co was 67.5 to 86.5% by mass, the amount of magnetostriction decreased in a quadratic curve form with the addition amount (not more than 1% by mass) of additive elements. When the material comprised 67.5 to 71.5% by mass of Co and 0.6% by mass of Nb, Mo, V, Ti, or Cr with the balance consisting of Fe and unavoidable impurities, for all the sample, the amount of magnetostriction was enhanced to not less than 110 ppm and, at the same time, the mechanical strength was larger than that of the sample free from the addition element.

All the addition elements (Nb, Mo, V, Ti, and Cr) enhance the mechanical strength through solid solution strengthening, and simultaneous addition of two or more elements offers the same effect as that when only one element is added. For example, the alloys having a composition comprising Co: 71.5% by mass, Nb: 0.36% by mass, and V: 0.24% by mass with the balance consisting of Fe and unavoidable impurities had the following properties: amount of magnetostriction 120 ppm and tensile strength 830 MPa.

The magnetostrictive materials having an enhanced mechanical strength are suitable for applications such as devices that are required to be durable, for example, vibration power generation and sensors utilizing an inverse magnetostriction effect. Vibration power generation and sensors utilizing an inverse magnetostriction effect, when force is applied repeatedly, are deformed and deteriorated. However, the used magnetostrictive materials having an enhanced mechanical strength can prolong the service life.

TABLE 2
Strength (tensile strength, Mpa)

| Additive | | | | |
|---|---|---|---|---|
| element | 0 | 0.2 | 0.6 | 1.0 |

Co 67.5

| | | | | |
|---|---|---|---|---|
| Nb | 660 | 725 | 852 | 980 |
| Mo | 660 | 715 | 825 | 930 |
| V | 660 | 700 | 782 | 870 |
| Ti | 660 | 698 | 780 | 873 |
| Cr | 660 | 695 | 765 | 836 |

Co 71.5

| | | | | |
|---|---|---|---|---|
| Nb | 681 | 740 | 875 | 1002 |
| Mo | 681 | 730 | 845 | 950 |
| V | 681 | 725 | 810 | 890 |
| Ti | 681 | 725 | 808 | 893 |
| Cr | 681 | 715 | 785 | 856 |

Co 86.5

| | | | | |
|---|---|---|---|---|
| Nb | 688 | 752 | 880 | 1010 |
| Mo | 688 | 745 | 852 | 955 |
| V | 688 | 730 | 823 | 900 |
| Ti | 688 | 725 | 821 | 899 |
| Cr | 688 | 728 | 799 | 870 |

TABLE 3
Magnetostriction (ppm)

| Additive | | | | |
|---|---|---|---|---|
| element | 0 | 0.2 | 0.6 | 1.0 |

Co 67.5

| | | | | |
|---|---|---|---|---|
| Nb | 132 | 126 | 115 | 80 |
| Mo | 132 | 127 | 120 | 88 |
| V | 132 | 128 | 122 | 98 |
| Ti | 132 | 128 | 122 | 99 |
| Cr | 132 | 125 | 118 | 80 |

Co 71.5

| | | | | |
|---|---|---|---|---|
| Nb | 144 | 135 | 124 | 90 |
| Mo | 144 | 137 | 130 | 97 |
| V | 144 | 139 | 132 | 110 |
| Ti | 144 | 138 | 135 | 113 |
| Cr | 144 | 131 | 120 | 88 |

Co 86.5

| | | | | |
|---|---|---|---|---|
| Nb | 115 | 110 | 93 | 65 |
| Mo | 115 | 112 | 101 | 73 |
| V | 115 | 113 | 97 | 80 |
| Ti | 115 | 110 | 97 | 81 |
| Cr | 115 | 105 | 94 | 68 |

1-6. (canceled)

7. A process for preparing a magnetostrictive material, the process comprising subjecting an alloy material to be converted to a magnetostrictive material to hot working and then to cold working, wherein
the alloy material has been produced by melting and solidifying a material comprising 67 to 87% by mass of Co and not more than 1% by mass of one of or a combination of at least two of Nb, Mo, V, Ti, and Cr with the balance consisting of Fe and unavoidable impurities.

8. The method for producing a magnetostrictive material according to claim 7, wherein heat treatment at 400 to 1000° C. is performed after hot working or cold working.

9. (canceled)

10. The method for producing a magnetostrictive material according to claim 7, wherein the hot working is hot forging or hot rolling.

11. The method for producing a magnetostrictive material according to claim 7, wherein the cold working is cold rolling.

12. The method for producing a magnetostrictive material according to claim 8, wherein the hot working is hot forging or hot rolling.

13. The method for producing a magnetostrictive material according to claim 8, wherein the cold working is cold rolling.

14. The method for producing a magnetostrictive material according to claim 10, wherein the cold working is cold rolling.
